(19) United States
(12) Patent Application Publication
(10) Pub. No.: US 2007/0254185 A1
(43) Pub. Date: Nov. 1, 2007

(54) Organic EL display device and organic thin film device

(76) Inventors: Shoicho Uchino, Annaka (JP); Akiko Iwata, Chiba (JP); Yoshihiro Arai, Mobara (JP); Tomio Yaguchi, Sagamihara (JP)

Correspondence Address: REED SMITH LLP, Suite 1400, 3110 Fairview Park Drive, Falls Church, VA, 22042, US

(21) Appl. No.: 11/783,578

(22) Filed: Apr. 10, 2007

(30) Foreign Application Priority Data
Apr. 12, 2006 (JP) 2006-109357

(51) Int. Cl. H01L 51/54; H01L 51/56

(52) U.S. Cl. 428/690; 428/917; 313/504; 313/506; 257/40; 257/E51.026; 427/66; 428/411.1

(57) ABSTRACT

An object of the invention is to provide a manufacturing method of an organic EL display device by fabricating a low molecular weight light emitting material on a lower electrode of an organic EL display device by an inkjet method. In order to achieve this object, in an organic EL display device including an organic material layer, the organic material layer is configured of a mixture of a low molecular weight material and a specified organic material. Concretely, at least one compound selected from 1,2,3-trimethoxytoleune, 1,2,3, 5-tetramethoxybenzene, 1,2-dimethoxy-5-bromobenzene, 3,4-dimethoxy-6-bromotoluene, 1,2,3-trimethoxy-5-bromo-benzene, and 3-bromo-1,2-benzodioxane is contained.

### CROSS-REFERENCE TO RELATED APPLICATIONS

The disclosure of Japanese Patent Application No. 2006-109357 filed on Apr. 12 2006 including the claims, the specification, the drawings and the abstract is incorporated herein by reference in its entirety.

### BACKGROUND OF THE INVENTION

1. Field of the Invention

The invention relates to an organic thin film device.

2. Description of the Related Art

An organic thin film device includes an organic EL display device and an organic thin film transistor. As a manufacturing method of an organic EL display device, there are known a method of fabricating a low molecular weight organic material by a vacuum vapor deposition method (vacuum vapor deposition method) and a method of fabricating a high molecular weight organic material by a wet method such as an inkjet method and a screen printing method. With respect to the vacuum vapor deposition method, since it is difficult to improve the registration of a mask, it is said that the manufacture of a large-sized EL device is difficult according to the current technologies. Also, there are drawbacks that use efficiency of a material is low and that the manufacture costs are high.

On the other hand, with respect to the wet method, since it is difficult to realize a high purity of a high molecular weight organic material, there is a drawback that a life of a formed device is short (especially in a blue color). A manufacturing method of an organic EL display device using such a high molecular weight organic material is described in Patent Document 1.

Patent Document 1: JP1999-54270A

### SUMMARY OF THE INVENTION

Since Patent Document 1 is limited to a precursor of a conjugated high molecular weight organic compound (difficult in sublimation purification), it is difficult to realize a high purity of the organic material as described previously. Thus, a life of the device was short. Then, the present inventors studied the fabrication of a low molecular weight organic material by a wet method.

In order to form a uniform organic material thin film in a desired region by an inkjet method, there are required (1) an inkviscosity is adjusted within an optimum range, thereby ensuring good ink discharge properties from a nozzle; and (2) crystallization or cohesion of an organic material in a drying process of ink droplets is suppressed, thereby forming a thin film only in a desired region.

Since a viscosity of a solvent for dissolving an organic material in light emitting devices or organic semiconductors is not more than 5 mPa·s, it was difficult so far to obtain an ink composition capable of stably discharging a low molecular weight organic material which can be subjected to distillation or sublimation purification by using an inkjet system with a droplet discharge capacity of 10 picoliters or more.

An object of the invention is to make it possible to manufacture an organic material of an organic EL display device to be configured of a low molecular weight organic material which can be subjected to distillation or sublimation purification by a wet method.

Another object of the invention is to make it possible to manufacture an organic material of an organic EL display device to be configured of a low molecular weight organic material which can be subjected to distillation or sublimation purification by a wet method.

In preparing an organic layer of an organic EL device of an organic EL display device by an inkjet method, there has hitherto been used an ink composition having a high molecular weight organic material dissolved in an aromatic solvent. FIG. 1 shows one example of a relationship between a boiling point and a viscosity of a solvent which is considered to be suitable for this ink composition and which is commercially available. As is clear from FIG. 1, a viscosity of the solvent suitable for the high molecular weight organic material is not more than 5mPa·s. In the case of a high molecular weight organic material, since when dissolved in a solvent, its viscosity may possibly increase several times, it is possible to obtain an optimum viscosity necessary for the ink discharge by inkjet even by using a solvent with low viscosity.

In general, an organic material which can be subjected to distillation or sublimation purification and which is represented by low molecular weight organic materials is low in solubility in a solvent and high in cohesiveness. For that reason, it has been considered to be difficult to form a uniform amorphous thin film. In particular, in the case of a low molecular weight organic material, since the low molecular weight organic material itself does not contribute to an increase of the viscosity, it is needed to use a solvent with high viscosity for the purpose of obtaining an ink composition which can be stably discharged.

However, an inkjet ink composition from which a viscosity necessary for stable discharge of an ink is obtainable has not been known yet.

Then, the present inventors made detailed investigations regarding a solvent suitable for an ink of a low molecular weight organic material which can be made highly pure by sublimation purification and studied a method of forming a low molecular weight organic material into an ink and manufacturing a low molecular weight organic EL device by an inkjet method. As a result, it has been found that a uniform amorphous film can be formed by a wet method represented by an inkjet method by forming an amorphous film by using an ink composition containing any one of compounds represented by the following chemical formulae C1 to C6.

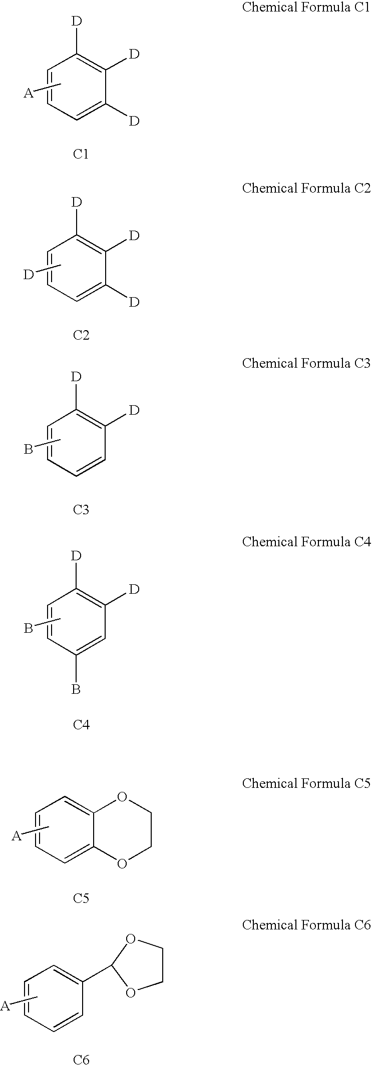

In the foregoing chemical formulae, A represents an alkyl group having not more than 4 carbon atoms. B represents chlorine or bromine. Also, D represents an electron-providing group and is a substituent selected among a dimethylamino group, a methoxy group, an ethoxy group, and a phenoxy group. Since this ink composition has a high boiling point, it has a characteristic feature that after drying, it remains more easily in a light emitting layer. Also, the aromatic compound of the invention has a characteristic feature that its hydrophobicity is higher than that of an organic material molecule of a light emitting material or the like to be dissolved.

Namely, in the case where an amorphous film is manufactured by using the foregoing ink composition, the compound represented by any one of the foregoing chemical formulae C1 to C6 can be made present in an organic material layer of an organic EL display device; and its organic material layer has high hydrophobicity and has an effect for inhibiting the penetration of a water molecule into an organic layer including a light emitting layer of an organic EL display device and is able to contribute to realization of a long life of an organic EL display device.

Also, specific examples of the aromatic compound represented by the chemical formula C1 include 2-eth-oxy-1,3-dimethoxybenzene, 1-ethoxy-2,3-dimethoxytoluene, 3-ethoxy-1,2-dimethoxytoluene, 1,2,3-trimethoxytoluene, 1,2,3-trimethoxy-5-ethylbenzene, 1,2,3-trimeth-oxy-5-(n-propyl)benzene, 1,2,3-trimethoxy-5-(isopropyl)-benzene, 1,2,3-trimethoxy-5-(n-butyl)benzene, 1,2,3-tri-methoxy-5-(tert-butyl)benzene, and 1,2,3-trimeth-oxy-5-(isobutyl)benzene.

Also, specific examples of the aromatic compound represented by the chemical formula C2 include 1,2,3,5-tetra-methoxybenzene.

Also, specific examples of the aromatic compound represented by the chemical formula C3 include 1,2-di-methoxy-4-bromobenzene and 1,2-dimethoxy-4-chlorobenzene.

Also, specific examples of the aromatic compound represented by the chemical formula C4 include 1,2-di-methoxy-4,5-dibromobenzene and 1,2-dimethoxy-4,5-dichloro-benzene.

Also, specific examples of the aromatic compound represented by the chemical formula C5 include 6-bromo-1,4-benzodioxane and 5-bromo-1,4-benzodioxane.

Also, specific examples of the aromatic compound represented by the chemical formula C6 include 2-(4-bromo-phenyl)-1, 3-dioxolan, 2-(3-bromophenyl) -1,3-dioxolan, and 2-(4-bromophenyl)-1,3-dioxolan.

As one example of a relationship between a boiling point and a viscosity of a solvent which is used in the invention, a relationship between a boiling point and a viscosity of an aromatic solvent which is considered to be suitable for a solvent of a high molecular weight light emitting material is shown in FIG. 2. It is noted that the solvent which is used in the invention has a high viscosity as compared with a solvent of a high molecular weight material and is suitable as an ink solvent of a low molecular weight light emitting material. Though the aromatic compounds represented by the chemical formulae C1 to C6include aromatic compounds which are solid at room temperature, even such an aromatic compound is also applicable as the solvent of the invention because it can be converted into a liquid state at room temperature upon mixing two or more kinds thereof.

According to the invention, it is possible to provide an organic EL display device resulting from fabrication of a low molecular weight organic layer by a wet method.

### BRIEF DESCRIPTION OF THE DRAWINGS

FIG. 1 is a graph to show a relationship between a boiling point and a viscosity of an aromatic solvent which is considered to be suitable for a solvent of a high molecular weight light emitting material.

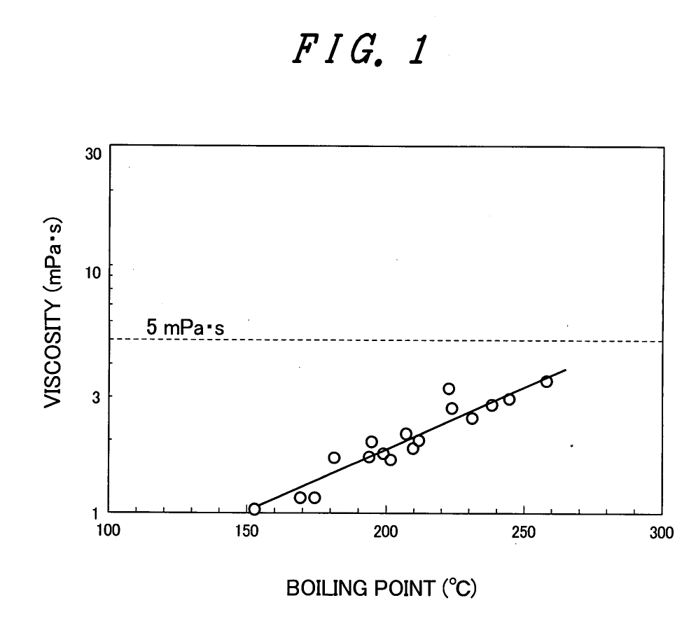

FIG. 2 is a graph to show a relationship between a boiling point and a viscosity of an aromatic solvent which is considered to be suitable for a solvent of a high molecular weight light emitting material with respect to one example of a relationship of a boiling point and a viscosity of a solvent which is used in the invention.

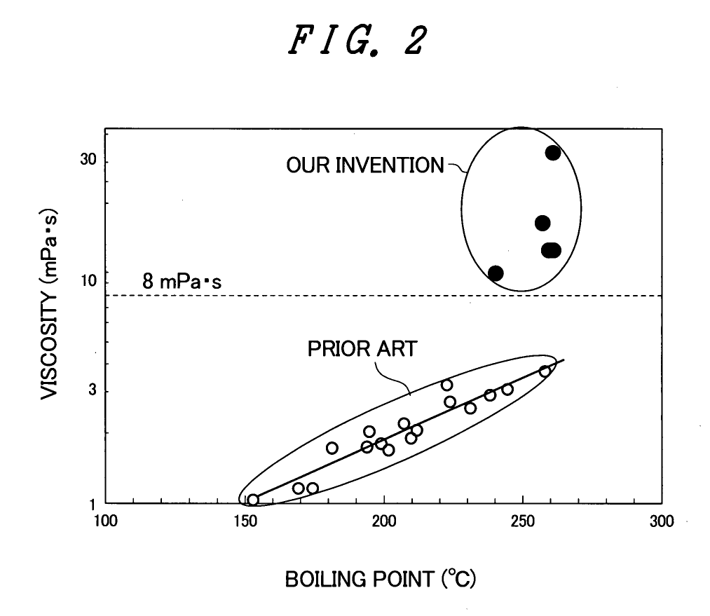

FIG. 3 is a view to show a cross-sectional structure of an organic EL display device of the invention.

### DETAILED DESCRIPTION OF THE INVENTION

Examples of the invention are described below.

### EXAMPLE 1

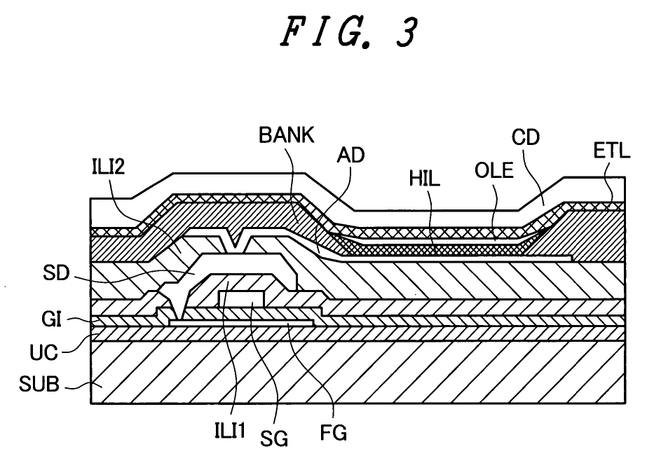

FIG. 3 shows a layer structure which is employed in the present Example. A structure in which a glass-made substrate SUB, an undercoat layer UC, a polysilicon layer FG, a gate insulating layer GI, a metallic gate electrode layer SG, a first interlayer insulating layer ILI1, a source·drain metallic layer SD, a second interlayer insulating layer ILI2, an EL device lower electrode layer AD, a bank BANK, an organic functional layer OEM (including a hole injection layer HIL, a light emitting layer OLE and an electron transport layer ETL), and an upper electrode CD are stacked in this order is provided on a first substrate. The substrate SUB is an alkali-free glass having a thickness of 1.1 mm. The undercoat layer UC is configured of a silicon nitride layer having a thickness of 150 nm and a silicon oxide layer having a thickness of 100 nm as formed by means of plasma CVD. The p-Si layer FG is formed in an island form in a forming place of a thin film transistor (hereinafter referred to as “TFT”) and a forming place of a capacitor CAP. Detailed forming places are described later with reference to the drawing.

The gate insulating layer GI is configured of a silicon oxide layer having a thickness of 110 nm, which is generally called a TEOS film. The metallic gate electrode layer SG is present on the gate insulating layer GI and is configured of MoW having a thickness of 150 nm in a superimposed region with the p-Si layer FG.

The first interlayer insulating layer ILI1 is configured of SiO having a thickness of 500 nm as formed in an upper layer of the metallic gate electrode layer SG and on the TEOS film of the gate insulating layer GI by means of plasma CVD. The source·drain metallic layer SD is configured of a stack structure of MoW/AlN/MoW having a thickness of 38 nm, 500 nm and 75 nm, respectively.

An aperture is formed in each of the foregoing gate insulating layer GI and first interlayer insulating layer ILI1 as the need arises; a source-drain layer is also formed in a side wall and a bottom part of the aperture; and a first contact hole to be connected in the stack structure of MoW/AlN/MoW is formed.

The second interlayer insulating layer ILI2 is configured of an SiN film having a thickness of 500 nm as formed on this first contact hole and the foregoing first interlayer insulating layer ILI1 by means of plasma CVD. Incidentally, this second interlayer insulating layer ILI2 is provided with a second contact hole as an aperture at a position deviated from the first contact hole. With respect to the lower electrode AD, ITO is fabricated in a thickness of 150 nm on the second interlayer insulating layer ILI2 by means of sputtering, subjected to patterning by etching a part thereof by a photolithography method and divided for every pixel. Also, the inside (side wall surface and bottom surface) of the second contact hole is also coated.

The bank BANK is a partition wall layer (bank) having a thickness of 2 μm by which pixels are partitioned so as to surround a pixel part. This is formed by subjecting a photosensitive resin composition containing an acrylic high molecular weight resin to patterning by a photolithography method. Incidentally, in order to impart ink repellency to the surface of the bank BANK, after forming the bank BANK, a fluorine plasma treatment was carried out.

A solution having 20% by weight of isopropyl alcohol added in a PEDOT/PSS aqueous solution (manufactured by Bayer AG) was passed through a PTFE-made filter of 0.45 μm to form a hole injection material ink, which was then fabricated in a thickness of 60 nm in a substrate pixel part by using an inkjet system to form a hole injection layer, followed by baking on a hot plate at 200° C. for 2.0 minutes, thereby forming the hole injection layer HIL. Incidentally, the hole injection layer HIL is formed on the lower electrode exposed from the aperture of the bank and a slope of the bank.

The light emitting layer OLE is an amorphous film formed by mixing 1,3,5-tris[4-(diphenylamino)phenyl]-benzene, tris[2-(2-pyridinyl)phenyl-C,N]-iridium/tris(2-phenylpyridine)iridium(III) (Ir(ppy)3) and 1,3-bis(5-p-t-butylphenyl)-1,3, 4-oxadizol-2-yl) benzene in a weight ratio of 100/80/6; dissolving the mixture in a 1/1 mixed solvent of 1,2,3-trimethoxybenzene and 3,4,5-trimethoxytoluene so as to have a solids concentration of 0.5% by weight; passing the solution through a PTFE-made filter of 0.2 μm to form a light emitting material ink (ink viscosity: 5 mPa·s); discharging the foregoing ink by using a piezoelectric type inkjet system; and baking the ink on a hot plate at 85° C. for 15 minutes to fabricate it in a thickness of 50 nm on the hole injection layer within the pixel.

In this light emitting layer OLE, slight amounts of 1,2,3-trimethoxybenzene and 3,4,5-trimethoxytoluene were detected even after baking. Accordingly, it may be said that this light emitting layer is a film with high waterproof properties.

The electron transport layer ETL is a film formed by after forming the light emitting layer OLE, vapor depositing tris(8-hydroxyquinolinato)aluminum(III) (Alq3) in a thickness of 10 nm at a vapor deposition rate of 0.1 nm/sec under vacuum of 10⁻⁶ Torr. In FIG. 3, while not given a symbol, after forming the electron transport layer ETL, LiF is vapor deposited in a thickness of 0.5 nm at a vapor deposition rate of 0.01 nm/sec. This is provided for the purpose of improving an electron injection ability by adjusting a work function at an interface with the upper electrode CD.

The upper electrode CD is an electrode formed by after the vapor deposition of LiF, vapor depositing Al in a thickness of 100 nm at a vapor deposition rate of 1 nm/sec. The foregoing adjustment of the work function at the interface is achieved by utilizing the matter that Li and F are separated due to vapor deposition energy of this Al to react with the adjacent Al vapor deposited film or electron transport layer ETL.

The thus obtained organic EL device was arranged in a globe box having an oxygen concentration of not more than 1 ppm, and a direct voltage was applied between ITO as a lower electrode (anode) and Al as an upper electrode (cathode), thereby achieving light emission. In a green pixel, green light emission with uniform luminance within the pixel was obtained by applying 10 V at a luminance of 1,080 cd/m². In each of a red pixel and a blue pixel, though the luminance was not measured, uniform light emission which is brighter than that of the related art could be confirmed.

### EXAMPLE 2

Au was vapor deposited in a thickness of 20 nm on a polyimide substrate having a thickness of 150 μm at a vapor deposition rate of 0.1 nm/sec under vacuum of 10⁻⁶Torr. This was subjected to patterning by a photolithography method, thereby forming a source-drain electrode. A source-to-drain channel length was set up at 10 μm.

Next, 1,3,5-tris[4-(diphenylamino)phenyl]-benzene (TDAPB, manufactured by Bayer AG) was dissolved in a 1/1 mixed solvent of 1,2,3-trimethoxybenzene and 3,4,5-trimethoxy-toluene so as to have a solids concentration of 0.5% by weight, and the solution was passed through a PTFE-made filter of 0.2 μm to form an organic semiconductor layer forming ink.

This ink was fabricated in a thickness of 50 nm on the hole injection layer within the pixel by using a piezoelectric type inkjet system and baked on a hot plate at 85° C. for 15 minutes, thereby obtaining an amorphous film.

Subsequently, an SiO₂ film having a thickness of 500 nm was formed as a gate insulating film by using a mixed gas of Ar (98.2% by volume), tetramethoxysilane (0.3% by volume) and an H₂ gas (1.5% by volume) and using an atmospheric plasma discharge system.

Finally, a gate electrode having a width of 20 μm was formed by using an Ag paste by means of screen printing, thereby obtaining an organic thin film transistor. A carrier mobility of the prepared organic thin film transistor was measured and found to be 1×10⁻⁵ cm²/Vs.

Furthermore, by applying this organic thin film transistor to an organic EL display device in place of the p-Si TFT of Example 1, it is possible to improve the display quality of a flexible and bendable organic EL display device. Namely, by configuring a pixel circuit by using this organic thin film transistor, stacking thereon a lower electrode exposed in an aperture of a bank having been subjected to a fluorine plasma treatment via an insulating film to connect to the foregoing pixel circuit, and forming a hole injection layer HIL, a hole transport layer HTL, an organic functional layer OEM, an electron transport layer ETL and a solid electrode of LiF/Al (common electrode over the whole of display pixels) on the outermost surface of the insulating film and the lower electrode, it is possible to improve an ability of the flexible organic EL display device.

What is claimed is:

1. An organic EL display device comprising an organic material layer, wherein the organic material layer contains any one of compounds represented by the following chemical formulae C1 to C6: 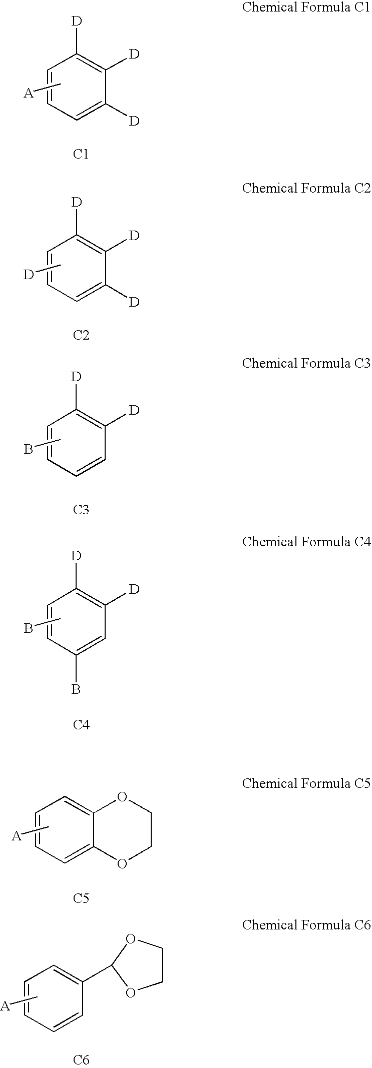
wherein A represents a substituent selected among alkyl groups having not more than 4 carbon atoms; B represents chlorine or bromine; and D represents an electron-providing substituent and is a substituent selected among a dimethylamino group, a methoxy group, an ethoxy group, and a phenoxy group, with at least two of them being a methoxy group.

2. The organic EL display device according to claim 1, wherein the organic material layer contains a material capable of emitting fluorescence or phosphorescence.

3. The organic EL display device according to claim 1, wherein the compound represented by any one of the chemical formulae C1 to C6 is at least one compound selected from 1,2,3-trimethoxytoleune, 1,2,3,5-tetramethoxybenzene, 1,2-dimethoxy-5-bromobenzene, 3,4-dimethoxy-6-bromotoluene, 1,2,3-trimethoxy-5-bromobenzene, and 3-bromo-1,2-benzodi-oxane.

4. The organic EL display device according to claim 1, wherein the compound represented by any one of the chemical formulae C1 to C6 is a mixture of aromatic compounds which are solid at room temperature.

5. The organic EL display device according to claim 1, wherein the compound represented by any one of the chemical formulae C1 to C6 has a viscosity of 8 mPa·s or more.

6. A manufacturing method of an organic thin film device comprising using an ink composition having an organic material which can be subjected to distillation or sublimation purification dissolved in at least one of aromatic compounds represented by the following chemical formulae C1 to C6 and forming an amorphous thin film in a recess partitioned by a partition wall layer by an inkjet method: 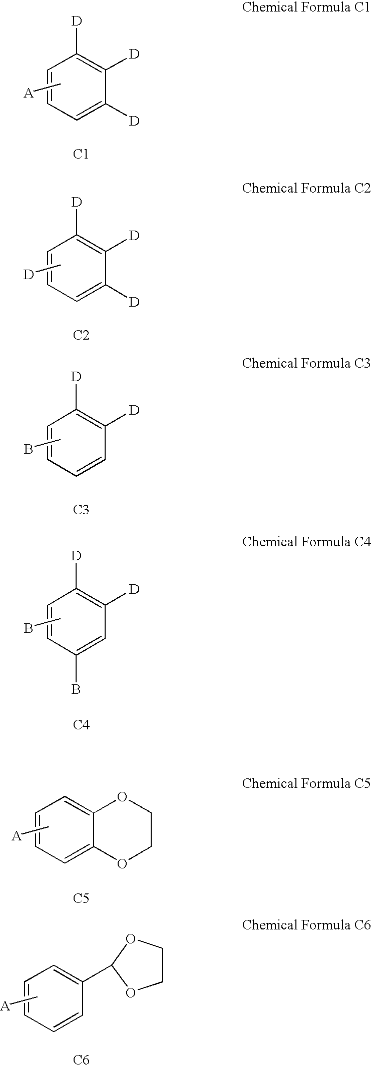
wherein A represents a substituent selected among alkyl groups having not more than 4 carbon atoms; B represents chlorine or bromine; and D represents an electron-providing substituent and is a substituent selected among a dimethylamino group, a methoxy group, an ethoxy group, and a phenoxy group, with at least two of them being a methoxy group.

7. The manufacturing method of an organic thin film device according to claim 6, wherein the organic material layer contains a material capable of emitting fluorescence or phosphorescence.

8. The manufacturing method of an organic thin film device according to claim 6, wherein the compound represented by any one of the chemical formulae C1 to C6 is at least one compound selected from 1,2,3-trimethoxytoleune, 1,2,3,5-tetramethyl-oxybenzene, 1,2-dimethoxy-5-bromobenzene, 3,4-dimeth-oxy-6-bromotoluene, 1,2,3-trimethoxy-5-bromobenzene, and 3-bromo-1,2-benzodioxane.

9. The manufacturing method of an organic thin film device according to claim 6, wherein the solvent of the ink composition is a mixture of aromatic compounds which are solid at room temperature.

10. The manufacturing method of an organic thin film device according to claim 6, wherein the solvent of the ink composition is a solvent having a viscosity of 8 mPa·s or more.
